(19) United States
(12) Patent Application Publication
(10) Pub. No.: US 2024/0321769 A1
(43) Pub. Date: Sep. 26, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Wen-Jung TSAI, Taichung City (TW); Wan-Chin CHUNG, Taichung City (TW); Chih-Chiang HE, Taichung City (TW); Chun-Chong CHIEN, Taichung City (TW)

(21) Appl. No.: 18/350,850

(22) Filed: Jul. 12, 2023

(30) Foreign Application Priority Data
Mar. 21, 2023 (TW) 112110501

(51) Int. Cl. H01L 23/552; H01L 21/56; H01L 23/495; H01L 23/498; H01L 23/66

(52) U.S. Cl. CPC H01L 23/552; H01L 21/565; H01L 23/49548; H01L 23/49816; H01L 23/66

(57) ABSTRACT

An electronic package and a manufacturing method thereof are provided, in which a plurality of electronic components and a shielding part are disposed on a carrier structure, the shielding part is located between two of the electronic components, and the plurality of electronic components and the shielding part are covered by an encapsulating layer, where a surface of the shielding part has a protruding portion. Therefore, a periphery surface of the shielding part is a non-straight surface, so as to prevent the reflection of electromagnetic waves in the encapsulating layer from interfering with the signal transmission of the electronic components.

### BACKGROUND

### 1. Technical Field

The present disclosure relates to a semiconductor device, and more particularly, to an electronic package with shielding function and a manufacturing method thereof.

### 2. Description of Related Art

With the evolution of semiconductor technology, various packaging products have been developed along with semiconductor products. Further, in order to improve electrical quality, various semiconductor products have shielding functions to prevent the generation of electromagnetic interference (EMI).

As shown in FIG. 1A to FIG. 1C, in a manufacturing method of a conventional semiconductor package 1, a plurality of semiconductor chips 11a, 11b and a passive component 11 are electrically connected on a packaging substrate 10, and then a packaging colloid 13 encapsulates each of the semiconductor chips 11a, 11b and the passive component 11, and a metal layer 14 is formed on the packaging colloid 13. The semiconductor package 1 protects the semiconductor chips 11a, 11b, the passive component 11 and the packaging substrate 10 via the packaging colloid 13 to prevent damage from external moisture or pollutants, and the plurality of semiconductor chips 11a, 11b are protected from external EMI by the metal layer 14.

However, the conventional semiconductor package 1 cannot avoid electromagnetic wave interference (EMI) between each of the semiconductor chips 11a, 11b inside the semiconductor package 1, resulting in signal errors easily.

Therefore, how to overcome the problems of the above-mentioned prior art has become an urgent problem to be solved at present.

### SUMMARY

In view of the aforementioned shortcomings of the prior art, the present disclosure provides an electronic package, which comprises: a carrier structure having a circuit layer; a plurality of electronic components disposed on the carrier structure and electrically connected to the circuit layer; a shielding part disposed on the carrier structure and located between any two of the plurality of electronic components, wherein a surface of the shielding part has a protruding portion; and an encapsulating layer formed on the carrier structure and covering the plurality of electronic components and the shielding part.

The present disclosure also provides a method of manufacturing an electronic package, the method comprises: providing a carrier structure with a circuit layer; disposing a plurality of electronic components and a shielding part on the carrier structure, wherein the plurality of electronic components are electrically connected to the circuit layer, and the shielding part is located between any two of the plurality of electronic components, wherein a surface of the shielding part has a protruding portion; and forming an encapsulating layer on the carrier structure to cover the plurality of electronic components and the shielding part.

In the aforementioned electronic package and method, at least one of the plurality of electronic components is a radio-frequency chip. For instance, the radio-frequency chip is a Bluetooth chip or a Wi-Fi chip.

In the aforementioned electronic package and method, the shielding part is exposed from the encapsulating layer.

In the aforementioned electronic package and method, an end surface of the shielding part is flush with a surface of the encapsulating layer.

In the aforementioned electronic package and method, the shielding part is a column, a plate, or a frame. For instance, the plate has a discontinuous wall. Further, the plate has notches or grooves. Alternatively, the plate has convex parts.

In the aforementioned electronic package and method, the electronic package further comprises a metal layer formed on the encapsulating layer. For instance, the metal layer is electrically connected to the shielding part. Alternatively, the circuit layer is electrically connected to the metal layer. Furthermore, a material of the metal layer is selected from copper, nickel, iron, aluminum, stainless steel, or a group composed thereof.

It can be seen from the above that in the electronic package and the manufacturing method thereof according to the present disclosure, the electronic package is designed with the shielding part to provide electromagnetic interference shielding to each of the electronic components. Hence, the electronic package of the present disclosure can prevent electromagnetic interference from occurring between the electronic components, thereby avoiding the problem of signal error.

In addition, the shielding part is designed with the protruding portion, so that the periphery surface of the shielding part is a non-straight surface, so as to prevent the reflection of electromagnetic waves in the encapsulating layer from interfering with the signal transmission of the electronic components. Hence, the electronic package of the present disclosure can further prevent electromagnetic interference from occurring between the electronic components, thereby avoiding the problem of signal error.

### BRIEF DESCRIPTION OF THE DRAWINGS

FIG. 1A, FIG. 1B and FIG. 1C are schematic cross-sectional views showing a manufacturing method of a conventional semiconductor package.

FIG. 2A-1, FIG. 2B, FIG. 2C, FIG. 2D and FIG. 2E are schematic cross-sectional views illustrating a manufacturing method of an electronic package according to a first embodiment of the present disclosure.

FIG. 2A-2 is a schematic partial cross-sectional view showing another aspect of FIG. 2A-1.

FIG. 2F is a schematic partial top view showing another aspect of FIG. 2E.

FIG. 3A and FIG. 3B are schematic cross-sectional views illustrating a manufacturing method of an electronic package according to a second embodiment of the present disclosure.

FIG. 3C-1 is a schematic partial top view showing another aspect of FIG. 3B.

FIG. 3C-2 is a schematic partial top view showing another aspect of FIG. 3C-1.

FIG. 3D is a schematic cross-sectional view showing one perspective of FIG. 3C-2.

FIG. 3E is a schematic partial top view showing another aspect of FIG. 3D.

FIG. 3F and FIG. 3G are schematic partial top views showing other aspects of FIG. 3C-1.

FIG. 4A, FIG. 4B and FIG. 4C are schematic cross-sectional views showing other different aspects of FIG. 3B.

FIG. 5 is a schematic cross-sectional view illustrating a manufacturing method of an electronic package according to a third embodiment of the present disclosure.

FIG. 6A is a schematic cross-sectional view illustrating a manufacturing method of an electronic package according to a fourth embodiment of the present disclosure.

FIG. 6B is a schematic partial top view showing another aspect of FIG. 6A.

FIG. 7A is a schematic cross-sectional view showing yet another aspect of FIG. 6A.

FIG. 7B is a schematic partial top view showing a different aspect of FIG. 7A.

FIG. 7C is a schematic cross-sectional view showing another aspect of FIG. 7A.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “above,” “first,” “second,” “a,” “one,” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

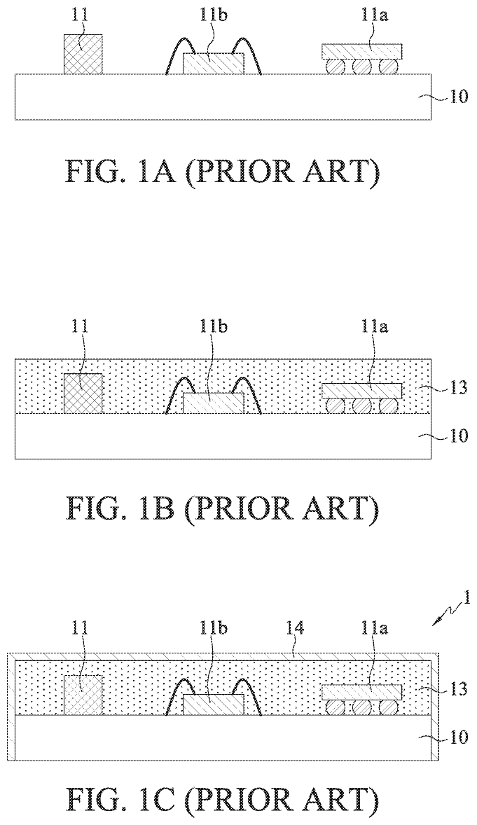

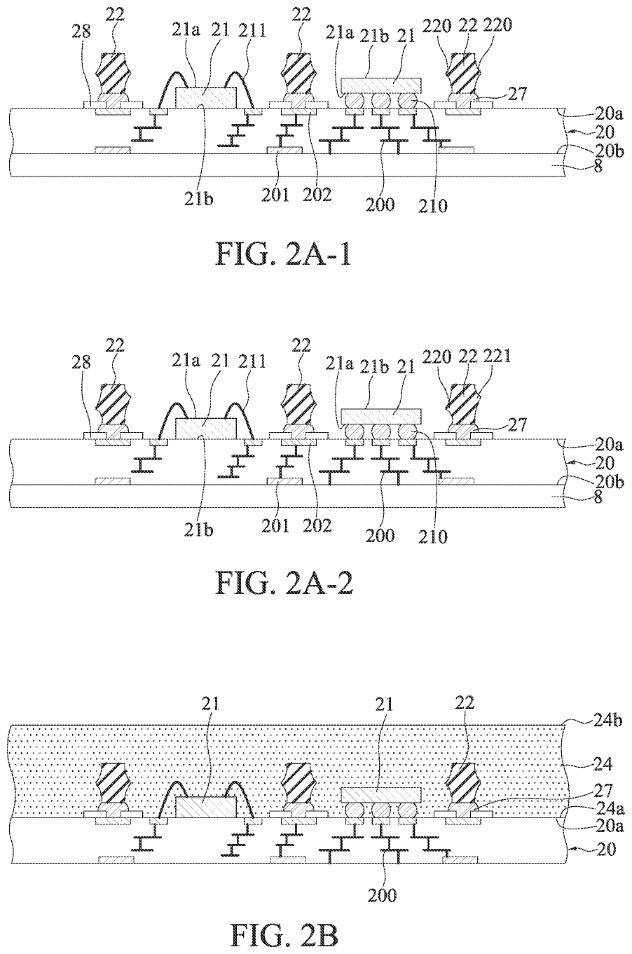

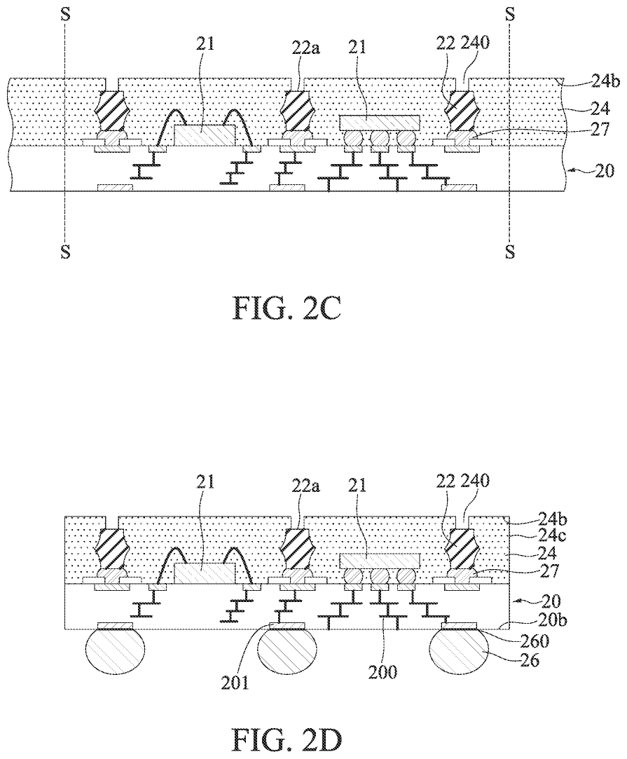

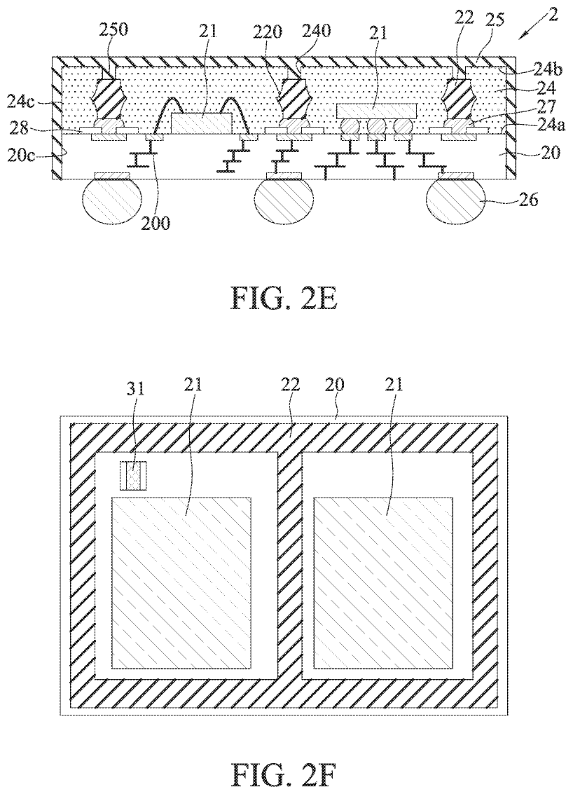

FIG. 2A-1, FIG. 2B, FIG. 2C, FIG. 2D and FIG. 2E are schematic cross-sectional views illustrating a manufacturing method of an electronic package 2 according to a first embodiment of the present disclosure.

As shown in FIG. 2A-1, a carrier structure 20 is provided and has a first side 20a and a second side 20b opposing the first side 20a, and a plurality of electronic components 21 and a plurality of shielding parts 22 separated from each other are disposed on the first side 20a of the carrier structure 20.

The carrier structure 20 is a circuit structure with a core layer or a coreless circuit structure, and the carrier structure 20 has an insulating layer and a circuit layer 200 formed on the insulating layer.

In an embodiment, the circuit layer 200 is of a fan-out redistribution layer (RDL) specification, and has a plurality of contacts 202 on the first side 20a and a plurality of ball placement pads 201 on the second side 20b. For instance, the material for forming the circuit layer 200 is copper, and the material for forming the insulating layer is a dielectric material such as polybenzoxazole (PBO), polyimide (PI), prepreg (PP), and the like. It should be understood that the carrier structure 20 can also be other carriers for carrying chips, such as organic plates, wafers, or other substrates with metal routings, but not limited to the above.

Moreover, in the manufacturing process related to the circuit layer 200, an insulating layer and a fan-out redistribution layer (RDL) can be formed on a supporting member 8, and there are various types of the supporting member 8, for example, the supporting member 8 is a wafer, a glass plate, an aluminum plate, a plate with aluminum layer on the surface, or other temporary plates, but not limited to the above.

The electronic component 21 is a package, an active element, a passive element, or a combination thereof, wherein the active element is such as a semiconductor chip, and the passive element is such as a resistor, a capacitor, or an inductor.

In an embodiment, the electronic component 21 is a radio-frequency chip (such as a Bluetooth chip or a Wi-Fi chip, but it can also be other electronic components not subject to electromagnetic interference), and the electronic component 21 has an active surface 21a and an inactive surface 21b opposing the active surface 21a. A plurality of electrode pads (not shown) are formed on the active surface 21a, and the electronic component 21 is disposed on the carrier structure 20 via a plurality of conductive bumps 210 such as solder materials in a flip-chip manner and is electrically connected to the circuit layer 200; alternatively, the electronic component 21 can be electrically connected to the circuit layer 200 via a plurality of bonding wires 211 in a wire-bonding manner. It should be understood that the way in which the electronic component 21 is electrically connected to the carrier structure 20 is not limited to the above.

The shielding part 22 is a column, a conductive material plate, or a frame and is disposed/erected on the carrier structure 20 and located at the periphery of each of the electronic components 21 and is electrically connected to the circuit layer 200 and grounded, such that the shielding parts 22 are served as electromagnetic barriers to prevent mutual electromagnetic (or signal) interference between the electronic components 21.

In an embodiment, the shielding part 22 is a metal pillar such as a copper pillar, and the shielding part 22 has a plurality of protruding portions 220 on the periphery surface thereof. For instance, the plurality of protruding portions 220 are formed on opposing two sides of the periphery surface of the shielding part 22, and positions of the protruding portions 220 can be equal or unequal in height (such as the protruding portions 220, 221 shown in FIG. 2A-2).

Furthermore, the shielding part 22 can be bonded onto the contact 202 via a solder material 27. For instance, an insulating protective layer 28 such as a solder-mask layer can be formed on the periphery of the contact 202 to facilitate the reflow of the solder material 27.

As shown in FIG. 2B, an encapsulating layer 24 is formed on the first side 20a of the carrier structure 20, such that the electronic components 21 and the shielding parts 22 are covered by the encapsulating layer 24. Then, the supporting member 8 is removed.

In an embodiment, the encapsulating layer 24 is made of an insulating material, such as polyimide (PI), dry film, epoxy resin, or molding compound, and the encapsulating layer 24 can be formed on the first side 20a of the carrier structure 20 by lamination or molding.

In addition, since the circuit layer 200 of the carrier structure 20 is of a redistribution layer (RDL) specification, the encapsulating layer 24 can thus be formed by adopting the molding specification of a wafer form.

Moreover, the encapsulating layer 24 has a first surface 24a and a second surface 24b opposing the first surface 24a, and the first surface 24a of the encapsulating layer 24 is bonded onto the first side 20a of the carrier structure 20.

As shown in FIG. 2C, a portion of the material of the second surface 24b of the encapsulating layer 24 is removed, so that end surfaces 22a of the shielding parts 22 are exposed from the second surface 24b of the encapsulating layer 24.

In an embodiment, a portion of the material of the second surface 24b of the encapsulating layer 24 is removed by laser or other hole forming methods to form a plurality of recesses 240 on the second surface 24b of the encapsulating layer 24, so that the end surfaces 22a of the shielding parts 22 are exposed from the recesses 240.

As shown in FIG. 2D, a singulation process is performed along a cutting path S shown in FIG. 2C, so that side surfaces 24c of the encapsulating layer 24 are formed, and the side surfaces 24c of the encapsulating layer 24 are adjacent to the first surface 24a and the second surface 24b. Then, a plurality of conductive components 26 such as solder balls are formed on the ball placement pads 201 on the second side 20b of the carrier structure 20 and are electrically connected to the circuit layer 200 for subsequent connection to electronic devices such as packaging structures, chips, or circuit boards (not shown).

In an embodiment, the shielding parts 22 are located inside the side surfaces 24c of the encapsulating layer 24 without being exposed from the side surfaces 24c of the encapsulating layer 24.

Furthermore, an under bump metallurgy (UBM) layer 260 can be formed on the ball placement pads 201 to facilitate the bonding of the conductive components 26.

As shown in FIG. 2E, a metal layer 25 is formed on the second surface 24b of the encapsulating layer 24, so that the electronic package 2 is obtained, wherein the metal layer 25 extends into the recesses 240 to form extensions 250, so that the metal layer 25 is in contact with the shielding parts 22 via the extensions 250, such that the metal layer 25 is electrically connected to the shielding parts 22, thereby serving as an EMI partition.

In an embodiment, the material for forming the metal layer 25 is gold (Au), silver (Ag), copper (Cu), nickel (Ni), iron (Fe), aluminum (Al), stainless steel (Sus), and the like. For instance, the metal layer 25 is formed by electroplating metal.

In addition, the metal layer 25 can also be formed by coating, sputtering, chemical plating, electroless plating, or vapor deposition. Alternatively, the metal layer 25 can be a metal cover plate or a conductive film and bonded on the second surface 24b of the encapsulating layer 24 by placing (such as by conductive bumps or direct lamination) or adhesion. It can be understood that there are various ways to form the metal layer 25, and the present disclosure is not limited to as such.

Moreover, the metal layer 25 can extend onto the side surfaces 24c of the encapsulating layer 24 and can even extend onto side surfaces 20c of the carrier structure 20.

Furthermore, as shown in FIG. 2F, an electronic component 31 configured as a passive element can be arranged on the first side 20a of the carrier structure 20, and the shielding parts 22 can be frames to surround and frame the electronic components 21, 31 in the form of multiple rings.

Therefore, in the manufacturing method of the electronic package 2 according to the first embodiment of the present disclosure, the electronic package 2 is designed with the shielding part 22 to provide electromagnetic interference (EMI) shielding to each of the electronic components 21, 31. Hence, compared to the prior art, the electronic package 2 according to the first embodiment of the present disclosure can prevent electromagnetic interference (EMI) from occurring between the electronic components 21, thereby avoiding the problem of signal error.

In addition, the shielding part 22 is designed with the protruding portions 220, 221, so that the periphery surface of the shielding part 22 is a non-straight surface such as a curved surface, so as to prevent the reflection of electromagnetic waves in the encapsulating layer 24 from interfering with the signal transmission of the electronic components 21. Hence, compared to the prior art, the electronic package 2 according to the first embodiment of the present disclosure can further prevent electromagnetic interference (EMI) from occurring between the electronic components 21, thereby avoiding the problem of signal error.

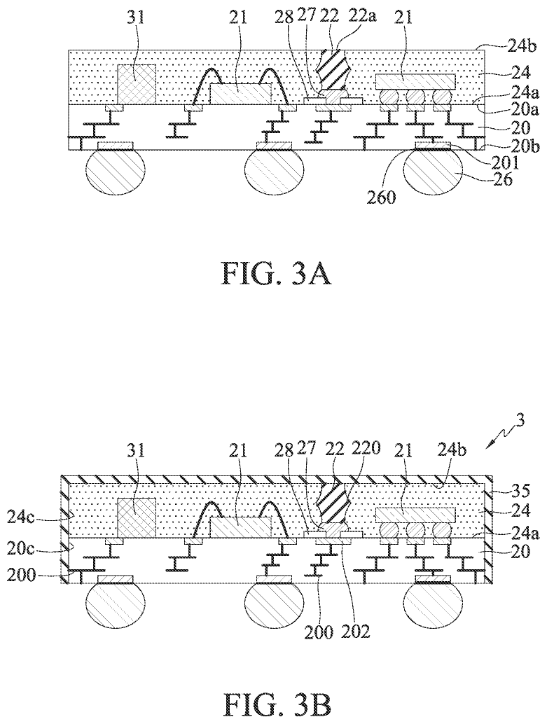

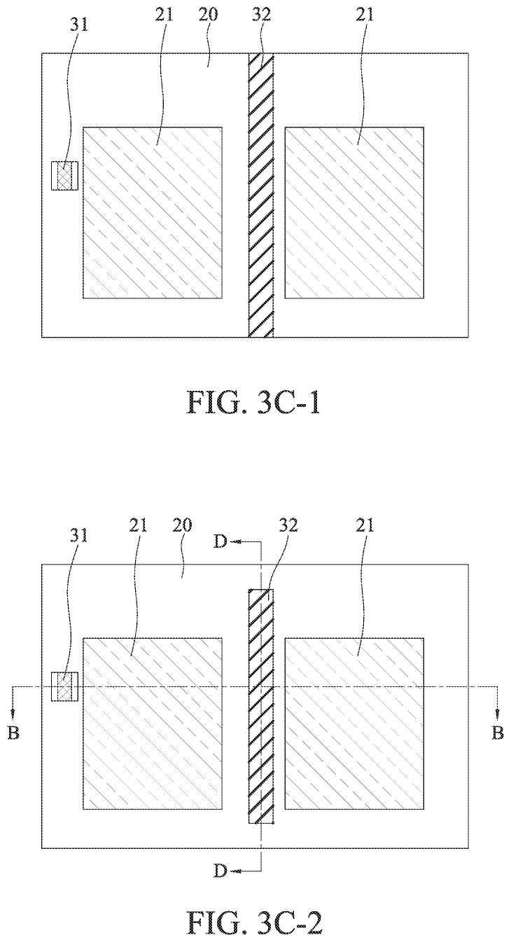

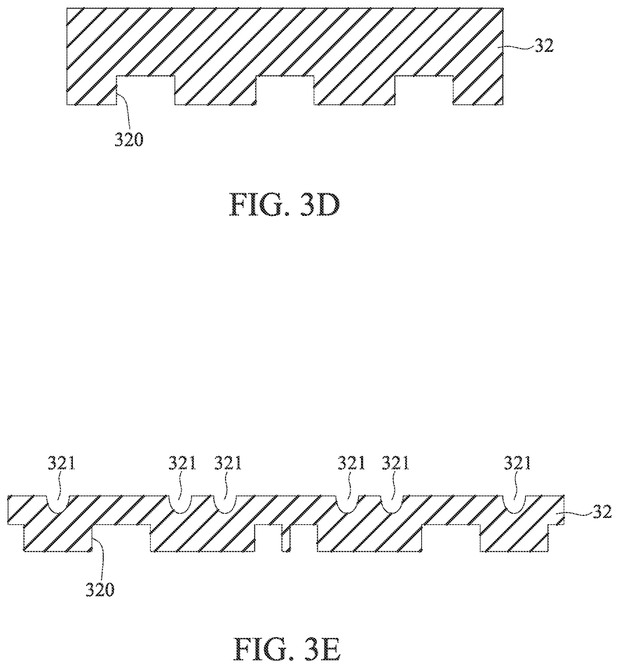

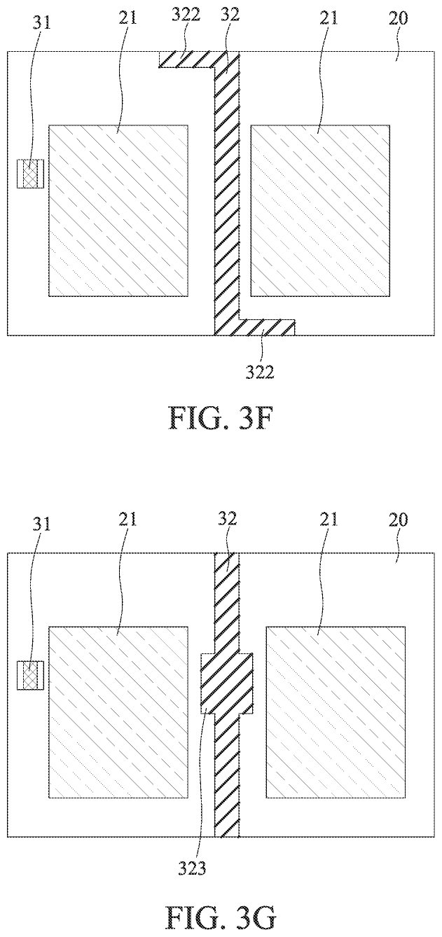

FIG. 3A and FIG. 3B are schematic cross-sectional views illustrating a manufacturing method of an electronic package 3 according to a second embodiment of the present disclosure. The difference between the second embodiment and the first embodiment lies in the manufacturing process of the encapsulating layer 24, and the other manufacturing processes are substantially the same, thus similarities between the second embodiment and the first embodiment will not be repeated below.

As shown in FIG. 3A to FIG. 3B, in the manufacturing process shown in FIG. 2C, a portion of the material of the second surface 24b of the encapsulating layer 24 is removed by grinding via a leveling process, so that the second surface 24b of the encapsulating layer 24 is flush with the end surfaces 22a of the shielding parts 22. Afterward, a singulation process is performed, and the plurality of conductive components 26 are formed. Lastly, a metal layer 35 is formed on the second surface 24b of the encapsulating layer 24, so that the metal layer 35 is in contact with the shielding part 22.

In an embodiment, the shielding part 22 is merely spaced between the two electronic components 21. Thus, in addition to using metal pillars, as shown in FIG. 3C-1 or FIG. 3C-2, a conductive material plate or wall can also be adopted as a shielding part 32. For instance, the plate of the shielding part 32 can have a discontinuous wall, such as bottom notches 320 shown in FIG. 3D or top grooves 321 shown in FIG. 3E; alternatively, as convex parts 322 at the ends of the shielding part 32 shown in FIG. 3F or convex parts 323 at the middle of the shielding part 32 shown in FIG. 3G, wherein the cross-section D-D shown in FIG. 3C-2 shows an aspect of the shielding part 32 of FIG. 3D, and the cross-section B-B shown in FIG. 3C-2 shows an aspect of the shielding part 22 of FIG. 3B.

Moreover, the metal layer 35 can also be electrically connected to the circuit layer 200 exposed from the side surfaces 20c of the carrier structure 20 so as to be grounded.

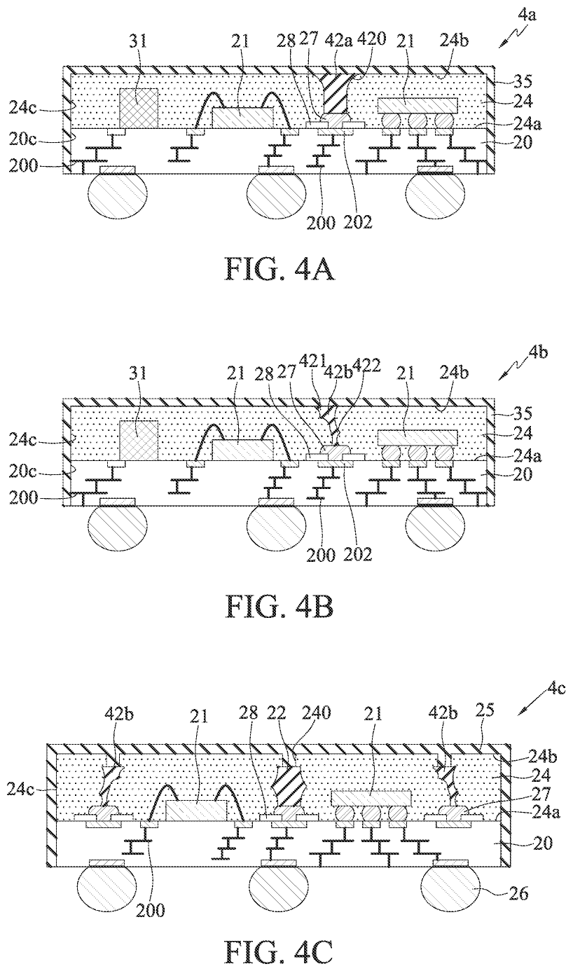

Furthermore, in another aspect, in an electronic package 4a of FIG. 4A, a protruding portion 420 can be formed at the end of a shielding part 42a and exposed from the second surface 24b of the encapsulating layer 24. For instance, the shielding part 42a is a horn-shaped pillar. It can be understood that the shielding part can have various shapes, as long as the shielding part has a protruding portion. For example, as shown in FIG. 4B, a shielding part 42b of an electronic package 4b has a plurality of protruding portions 421, 422 having different dimensions/sizes, but the present disclosure is not limited to as such.

In addition, in another aspect, the shielding parts 22, 42b with different shapes can be adopted in an electronic package according to requirements, as shown by an electronic package 4c in FIG. 4C.

Therefore, in the manufacturing method of the electronic package 3, 4a, 4b, 4c according to the second embodiment of the present disclosure, the electronic package 3, 4a, 4b, 4c is designed with the shielding part 22, 32, 42a, 42b to provide electromagnetic interference (EMI) shielding to each of the electronic components 21. Hence, compared to the prior art, the electronic package 3, 4a, 4b, 4c according to the second embodiment of the present disclosure can prevent electromagnetic interference (EMI) from occurring between the electronic components 21, thereby avoiding the problem of signal error.

Moreover, the shielding part 22, 32, 42a, 42b is designed with the protruding portion 220, 420, 421, 422, so that the periphery surface of the shielding part 22, 32, 42a, 42b is a non-straight surface such as a curved surface (even an irregular surface), so as to prevent the reflection of electromagnetic waves in the encapsulating layer 24 from interfering with the signal transmission of the electronic components 21. Hence, compared to the prior art, the electronic package 3, 4a, 4b, 4c according to the second embodiment of the present disclosure can further prevent electromagnetic interference (EMI) from occurring between the electronic components 21, thereby avoiding the problem of signal error.

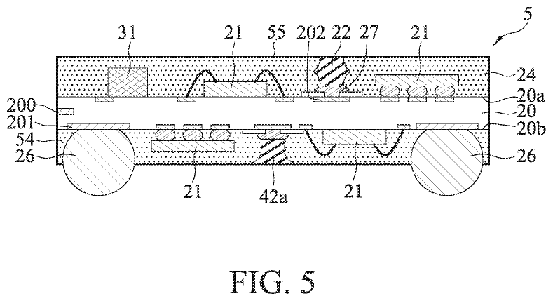

FIG. 5 is a schematic cross-sectional view illustrating a manufacturing method of an electronic package 5 according to a third embodiment of the present disclosure. The difference between the third embodiment and the above embodiments lies in the packaging means, and the other manufacturing processes are substantially the same, thus similarities between the third embodiment and the above embodiments will not be repeated below.

As shown in FIG. 5, the electronic components 21 and the shielding part 42a separated from each other can be disposed on the second side 20b of the carrier structure 20 of the second embodiment, and the electronic components 21, the shielding part 42a and the conductive components 26 are covered by a packaging layer 54, wherein the conductive components 26 are protruded from the packaging layer 54.

In an embodiment, the packaging layer 54 is made of an insulating material, such as polyimide (PI), dry film, epoxy resin, or molding compound, and the packaging layer 54 can be formed on the second side 20b of the carrier structure 20 by lamination or molding. It can be understood that the material for forming the packaging layer 54 and the material for forming the encapsulating layer 24 can be the same or different.

Furthermore, the packaging layer 54 and the encapsulating layer 24 can be fabricated in the same manufacturing process to form a single package.

In addition, a metal layer 55 also extends onto the packaging layer 54 to cover the electronic components 21 and the plurality of shielding parts 22, 42a on the first side 20a and the second side 20b.

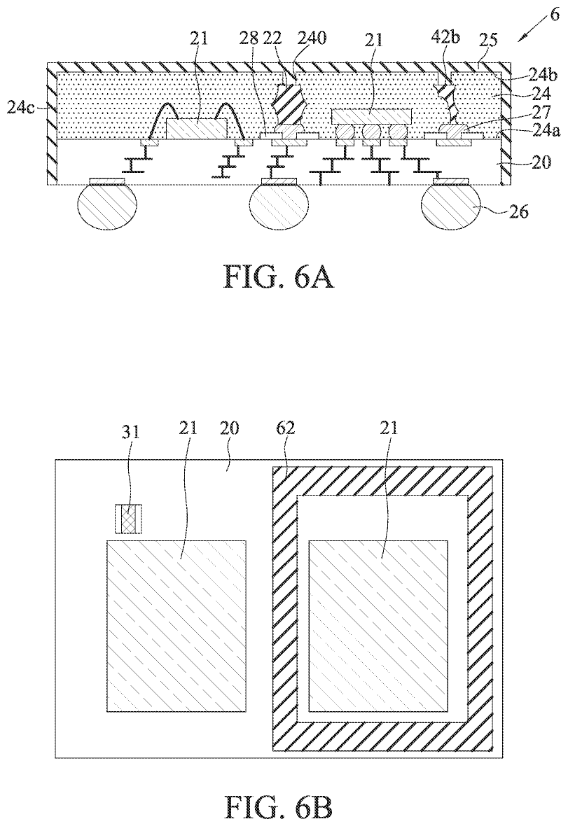

FIG. 6A and FIG. 6B are schematic views illustrating a manufacturing method of an electronic package 6 according to a fourth embodiment of the present disclosure. The difference between the fourth embodiment and the above embodiments lies in the shape of the shielding part, and the other manufacturing processes are substantially the same, thus similarities between the fourth embodiment and the above embodiments will not be repeated below.

As shown in the electronic package 6 of FIG. 6A, a single electronic component 21 is surrounded by the plurality of shielding parts 22, 42b with different aspects on the first side 20a of the carrier structure 20 of the first embodiment. Alternatively, as shown in FIG. 6B, a shielding part 62 of a frame is disposed on the first side 20a of the carrier structure 20 of the first embodiment, and the shielding part 62 surrounds and frames the single electronic component 21 in the form of a single ring.

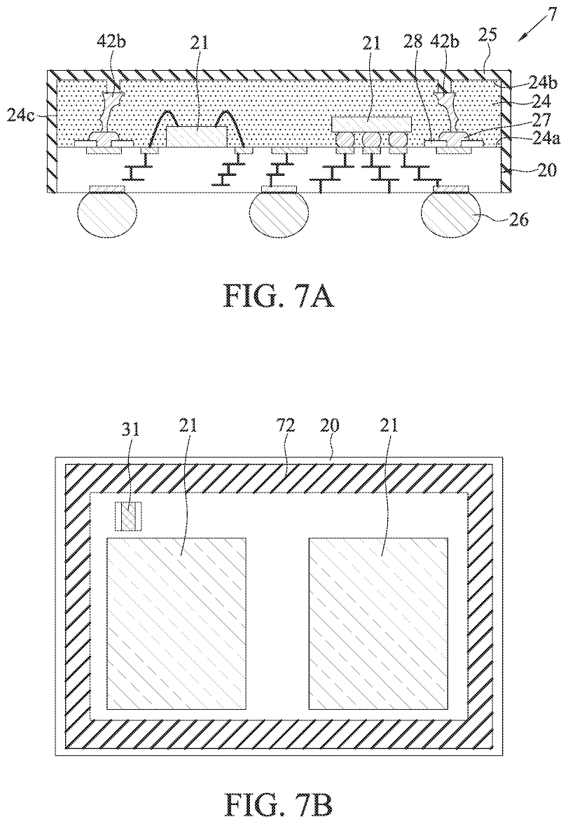

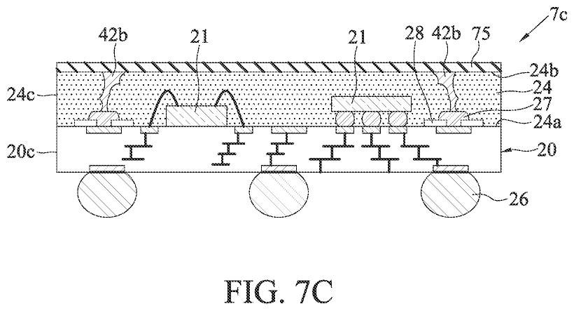

It can be understood that, in an electronic package 7 of FIG. 7A, the plurality of shielding parts 42b with the same aspect surround all the electronic components 21; alternatively, as shown in FIG. 7B, a shielding part 72 can also surround all the electronic components 21 in a form of a single ring.

On the other hand, in all the above embodiments, a metal layer 75 can merely be formed on the second surface 24b of the encapsulating layer 24, as shown in an electronic package 7c of FIG. 7C, so that the side surfaces 24c of the encapsulating layer 24 and the side surfaces 20c of the carrier structure 20 are exposed. Accordingly, the EMI protection above the electronic package 7c can be provided by the metal layer 75, and the side EMI protection can be provided by the shielding part 42b.

The present disclosure also provides an electronic package 2, 3, 4a, 4b, 4c, 5, 6, 7, 7c, which comprises: a carrier structure 20 with a circuit layer 200, a plurality of electronic components 21, 31, at least one shielding part 22, 32, 42a, 42b, 62, 72, and an encapsulating layer 24.

The electronic components 21, 31 are disposed on the carrier structure 20 and electrically connected to the circuit layer 200.

The shielding part 22, 32, 42a, 42b, 62, 72 is disposed on the carrier structure 20 and located between any two of the plurality of electronic components 21, wherein a surface of the shielding part 22, 32, 42a, 42b, 62, 72 has a protruding portion 220, 221, 420, 421, 422.

The encapsulating layer 24 is formed on the carrier structure 20 to encapsulate the plurality of electronic components 21, 31 and the shielding part 22, 32, 42a, 42b, 62, 72.

In an embodiment, at least one of the plurality of electronic components 21 is a radio-frequency chip. For instance, the radio-frequency chip is a Bluetooth chip or a Wi-Fi chip.

In an embodiment, the shielding part 22, 42a, 42b is exposed from the encapsulating layer 24.

In an embodiment, the surface (such as end surface 22a) of the shielding part 22, 42a, 42b is flush with a second surface 24b of the encapsulating layer 24.

In an embodiment, the shielding part 22, 32, 42a, 42b, 62, 72 is a column, a plate, or a frame. For instance, the plate has a discontinuous wall. Further, the plate has notches 320 or grooves 321. Alternatively, the plate has convex parts 322, 323.

In an embodiment, the electronic package 2, 3, 4a, 4b, 4c, 5, 6, 7 further comprises a metal layer 25, 35, 55, 75 formed on the encapsulating layer 24. For instance, the metal layer 25, 35, 55, 75 is electrically connected to the shielding part 22, 32, 42a, 42b, 62, 72. Alternatively, the circuit layer 200 is electrically connected to the metal layer 25, 35, 55. Furthermore, a material of the metal layer 25, 35, 55, 75 is selected from copper, nickel, iron, aluminum, stainless steel, or a group composed thereof.

To sum up, in the electronic package and the manufacturing method thereof according to the present disclosure, the electronic package is designed with the shielding part to provide electromagnetic interference shielding to each of the electronic components. Hence, the electronic package of the present disclosure can prevent electromagnetic interference from occurring between the electronic components, thereby avoiding the problem of signal error.

Besides, the shielding part is designed with the protruding portion, so that the periphery surface of the shielding part is a non-straight surface, so as to prevent the reflection of electromagnetic waves in the encapsulating layer from interfering with the signal transmission of the electronic components. Hence, the electronic package of the present disclosure can further prevent electromagnetic interference from occurring between the electronic components, thereby avoiding the problem of signal error.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a circuit layer;
a plurality of electronic components disposed on the carrier structure and electrically connected to the circuit layer;
a shielding part disposed on the carrier structure and located between any two of the plurality of electronic components, wherein a surface of the shielding part has a protruding portion; and
an encapsulating layer formed on the carrier structure and covering the plurality of electronic components and the shielding part.

2. The electronic package of claim 1, wherein at least one of the plurality of electronic components is a radio-frequency chip.

3. The electronic package of claim 2, wherein the radio-frequency chip is a Bluetooth chip or a Wi-Fi chip.

4. The electronic package of claim 1, wherein the shielding part is exposed from the encapsulating layer.

5. The electronic package of claim 1, wherein an end surface of the shielding part is flush with a surface of the encapsulating layer.

6. The electronic package of claim 1, wherein the shielding part is a column, a plate, or a frame.

7. The electronic package of claim 6, wherein the plate has a discontinuous wall.

8. The electronic package of claim 7, wherein the plate has notches or grooves.

9. The electronic package of claim 7, wherein the plate has convex parts.

10. The electronic package of claim 1, further comprising a metal layer formed on the encapsulating layer.

11. The electronic package of claim 10, wherein the metal layer is electrically connected to the shielding part.

12. The electronic package of claim 10, wherein the circuit layer is electrically connected to the metal layer.

13. The electronic package of claim 10, wherein a material of the metal layer is selected from copper, nickel, iron, aluminum, stainless steel, or a group composed thereof.

14. A method of manufacturing an electronic package, the method comprising:
providing a carrier structure with a circuit layer;
disposing a plurality of electronic components and a shielding part on the carrier structure, wherein the plurality of electronic components are electrically connected to the circuit layer, and the shielding part is located between any two of the plurality of electronic components, wherein a surface of the shielding part has a protruding portion; and
forming an encapsulating layer on the carrier structure to cover the plurality of electronic components and the shielding part.

15. The method of claim 14, wherein at least one of the plurality of electronic components is a radio-frequency chip.

16. The method of claim 15, wherein the radio-frequency chip is a Bluetooth chip or a Wi-Fi chip.

17. The method of claim 14, wherein the shielding part is exposed from the encapsulating layer.

18. The method of claim 14, wherein an end surface of the shielding part is flush with a surface of the encapsulating layer.

19. The method of claim 14, wherein the shielding part is a column, a plate, or a frame.

20. The method of claim 19, wherein the plate has a discontinuous wall.

21. The method of claim 20, wherein the plate has notches or grooves.

22. The method of claim 20, wherein the plate has convex parts.

23. The method of claim 14, further comprising forming a metal layer on the encapsulating layer.

24. The method of claim 23, wherein the metal layer is electrically connected to the shielding part.

25. The method of claim 23, wherein the circuit layer is electrically connected to the metal layer.

26. The method of claim 23, wherein a material of the metal layer is selected from copper, nickel, iron, aluminum, stainless steel, or a group composed thereof.
